(19) United States
(12) Patent Application Publication
(10) Pub. No.: US 2026/0332154 A1
(43) Pub. Date: Oct. 22, 2026

(54) STAND-ALONE PCB MODULE INTEGRATED WITH FORCE-BASED AND STRAIN-BASED SENSORS

(71) Applicant: Qorvo US, Inc., Greensboro, NC (US)

(72) Inventors: Robert Aigner, Ocoee, FL (US); Marcus Granger-Jones, Scotts Valley, CA (US)

(21) Appl. No.: 19/642,134

(22) Filed: Apr. 8, 2026

Related U.S. Application Data
(60) Provisional application No. 63/790,106, filed on Apr. 17, 2025.

(51) Int. Cl. H03L 7/099

(52) U.S. Cl. CPC H03L 7/0991

(57) ABSTRACT

Embodiments of a resonator clock are disclosed. The resonator clock may include a first oscillator circuit, second oscillator circuit, and output clock circuit, and a phase lock loop. The first and second oscillator circuits generate first and second oscillator clock signals that have a frequency offset. The first and second oscillator circuits may have acoustic wave devices that are different so as to produce the frequency offset. The output clock circuit is configured to receive the first oscillator clock signal and generate an output clock signal having an output clock frequency. A mixer mixes the first oscillator clock signal and the second oscillator clock signal so that the phase lock loop is configured to generate a reference clock signal having a reference clock frequency that indicates the frequency offset. The phase lock loop is configured to drive the output clock frequency to a set relationship with the reference clock frequency.

### RELATED APPLICATIONS

This application claims the benefit of provisional patent application Ser. No. 63/790,106, filed Apr. 17, 2025, the disclosure of which is hereby incorporated herein by reference in its entirety.

### FIELD OF THE DISCLOSURE

This disclosure relates to resonator clocks and methods of operating the same.

### BACKGROUND

Quartz crystals dominate the timing reference market due to their ability to achieve highly accurate frequency tolerances and minimal temperature drift. These crystals exhibit high quality (Q) factors, which results in exceptionally low phase noise. To further enhance stability, electronic compensation can be applied by measuring temperature and fine-tuning the oscillator's frequency using a series or shunt capacitor. This adjustment allows for precise frequency control within a fraction of a percent.

However, quartz crystals face limitations in miniaturization efforts for wireless systems because the physical dimensions of the crystal plate dictate the overall size of the component. Additionally, these crystals require delicate hermetic cavity packages to protect them from environmental stress. Inside the package, the crystal must be mechanically decoupled to prevent stress-induced frequency inaccuracies. Another drawback is that quartz crystal oscillators typically cannot support frequencies above 100 MHz without additional circuitry to synthesize higher frequency references, which adds complexity to their design.

### SUMMARY

Embodiment 1. A resonator clock, includes: a first oscillator circuit includes a first acoustic wave device, wherein the first oscillator circuit is configured to generate a first oscillator clock signal with the first acoustic wave device; a second oscillator circuit includes a second acoustic wave device, wherein the second oscillator circuit is configured to generate a second oscillator clock signal with the second acoustic wave device, and wherein the first acoustic wave device and the second acoustic wave device are different; an output clock circuit configured to receive the first oscillator clock signal and generate an output clock signal having an output clock frequency; and a phase lock loop, wherein: the phase lock loop includes a mixer configured to mix the first oscillator clock signal and the second oscillator clock signal so that the phase lock loop is configured to generate a reference clock signal having a reference clock frequency; and the phase lock loop is configured to drive the output clock frequency to a set relationship with the reference clock frequency.

Embodiment 2. The resonator clock of embodiment 1, wherein the first acoustic wave device and the second acoustic wave device are different such that the first oscillator clock signal has a first oscillator clock frequency and the second oscillator clock signal has a second oscillator clock frequency, and wherein the first oscillator clock frequency and the second oscillator clock frequency are different.

Embodiment 3. The resonator clock of embodiment 2, wherein the first acoustic wave device and the second acoustic wave device are monolithic but are different by having at least one layer that is different such that the first oscillator clock frequency and the second oscillator clock frequency are different.

Embodiment 4. The resonator clock of embodiment 1, wherein the set relationship is the output clock frequency equaling the reference clock frequency.

Embodiment 5. The resonator clock of embodiment 4, wherein the output clock circuit includes a frequency divider, wherein the frequency divider is configured to: receive the first oscillator clock signal having a first oscillator clock frequency; generate the output clock signal in response to the first oscillator clock signal, the output clock signal having an output clock signal frequency that is the first oscillator clock frequency divided by an divisor value.

Embodiment 6. The resonator clock of embodiment 5, wherein: the frequency divider is an intermediary frequency divider; the output clock signal is an intermediary output clock signal; the output clock signal has an intermediary output clock signal frequency; the divisor value is an intermediary divisor value; the output clock circuit further includes a final frequency divider; and the final frequency divider is configured to: receive the intermediary output clock signal; and generate a final output clock signal in response to the intermediary output clock signal, the final output clock signal having a final output clock signal frequency that is the intermediary output clock signal frequency divided by a second divisor value.

Embodiment 7. The resonator clock of embodiment 1, wherein: the first acoustic wave device and the second acoustic wave device are different such that the first oscillator clock signal has a first oscillator clock frequency and the second oscillator clock signal has a second oscillator clock frequency and wherein the first oscillator clock frequency and the second oscillator clock frequency are different; the mixer is a double side band mixer that is configured to generate a composite reference clock signal having a higher frequency reference clock signal and a lower frequency reference clock signal, the higher frequency reference clock signal having a frequency equal to the first oscillator clock frequency added to the second oscillator clock frequency, and the lower frequency reference clock signal having a frequency equal to the first oscillator clock frequency minus the second oscillator clock frequency; and the phase lock loop further includes: a low pass filter configured to filter the higher frequency reference clock signal from the composite reference clock signal so that a reference clock signal is generated that is the lower frequency reference clock signal; and a phase detector configured to receive the reference clock signal and the output clock signal and generate a phase error signal that indicates a frequency difference between the output clock signal and the reference clock signal.

Embodiment 8. The resonator clock of embodiment 7, wherein the low pass filter is a first low pass filter, and the phase detector includes a second low pass filter that is configured to filter the phase error signal.

Embodiment 9. The resonator clock of embodiment 7, further includes a control circuit operably associated with the first oscillator circuit, wherein the control circuit is configured to drive the output clock frequency to the set relationship with the reference clock frequency based on the phase error signal.

Embodiment 10. The resonator clock of embodiment 1, wherein: the first acoustic wave device and the second acoustic wave device are different such that the first oscillator clock signal has a first oscillator clock frequency and the second oscillator clock signal has a second oscillator clock frequency and wherein the first oscillator clock frequency and the second oscillator clock frequency are different; the mixer is a single side band mixer that is configured to generate a reference clock signal having a frequency equal to the first oscillator clock frequency minus the second oscillator clock frequency; and the phase lock loop further includes a phase detector configured to receive the reference clock signal and the output clock signal and generate a phase error signal that indicates a frequency difference between the output clock signal and the reference clock signal.

Embodiment 11. The resonator clock of embodiment 10, further includes a control circuit operably associated with the first oscillator circuit, wherein the control circuit is configured to drive the output clock frequency to the set relationship with the reference clock frequency based on the phase error signal.

Embodiment 12. The resonator clock of embodiment 10, the mixer is a first mixer and wherein the single side band mixer includes: a first I/Q generator circuit configured to generate a first in-phase signal and a first quadrature signal based on the first oscillator clock signal; a second I/Q generator circuit configured to generate a second in-phase signal and a second quadrature signal based on the second oscillator clock signal; a second mixer configured to mix the first in-phase signal and the second in-phase signal so as to generate a mixed in-phase signal; a third mixer configured to mix the first quadrature signal and the second quadrature signal to generate a mixed quadrature signal; and a signal adder configured to add the mixed in-phase signal and the mixed quadrature signal so as to generate the reference clock signal.

Embodiment 13. The resonator clock of embodiment 10, wherein the single side band mixer includes: a first I/Q generator circuit configured to generate a first in-phase signal and a first quadrature signal based on first oscillator clock signal; a second I/Q generator circuit configured to generate a second in-phase signal and a second quadrature signal based on second oscillator clock signal; a first XOR gate configured to mix the first in-phase signal and the second in-phase signal so as to generate a mixed in-phase signal; a second XOR gate configured to mix the first quadrature signal and the second quadrature signal to generate a mixed quadrature signal; and a signal adder configured to add the mixed in-phase signal and the mixed quadrature signal so as to generate the reference clock signal.

Embodiment 14. The resonator clock of embodiment 10, wherein the control circuit is a digital control circuit, the phase lock loop further includes: a first digital-to-analog converter between the digital control circuit and the first oscillator circuit; a second digital-to-analog converter between the digital control circuit and the second oscillator circuit.

Embodiment 15. A clock generating method, includes: generating a first oscillator clock signal with a first acoustic wave device in a first oscillator circuit; generating a second oscillator clock signal with a second acoustic wave device in a second oscillator circuit, wherein the first acoustic wave device and the second acoustic wave device are different; generate an output clock signal with a first oscillator clock signal, the output clock signal having an output clock frequency; mix the first oscillator clock signal and the second oscillator clock signal so that the phase lock loop is configured to generate a reference clock signal having a reference clock frequency; and drive the output clock frequency to a set relationship with the reference clock frequency.

Embodiment 16. A user element includes a reference clock, the reference clock includes: a first oscillator circuit includes a first acoustic wave device, wherein the first oscillator circuit is configured to generate a first oscillator clock signal with the first acoustic wave device; a second oscillator circuit includes a second acoustic wave device, wherein the second oscillator circuit is configured to generate a second oscillator clock signal with the second acoustic wave device, wherein the first acoustic wave device and the second acoustic wave device are different; and an output clock circuit configured to receive the first oscillator clock signal and generate an output clock signal having an output clock frequency; a phase lock loop, wherein: the phase lock loop includes a mixer configured to mix the first oscillator clock signal and the second oscillator clock signal so that the phase lock loop is configured to generate a reference clock signal having a reference clock frequency; and the phase lock loop is configured to drive the output clock frequency to a set relationship with the reference clock frequency.

Embodiment 17. The user element of embodiment 16, wherein the first acoustic wave device and the second acoustic wave device are different such that the first oscillator clock signal has a first oscillator clock frequency and the second oscillator clock signal has a second oscillator clock frequency, and wherein the first oscillator clock frequency and the second oscillator clock frequency are different.

Embodiment 18. The user element of embodiment 17, wherein the first acoustic wave device and the second acoustic wave device are monolithic but are different by having at least one layer that is different such that the first oscillator clock frequency and the second oscillator clock frequency are different.

Embodiment 19. The user element of embodiment 16, wherein the set relationship is the output clock frequency equaling the reference clock frequency.

Embodiment 20. The user element of embodiment 19, wherein the output clock circuit includes a frequency divider wherein the frequency divider is configured to: receive the first oscillator clock signal having a first oscillator clock frequency; generate the output clock signal in response to the first oscillator clock signal, the output clock signal having an output clock signal frequency that is the first oscillator clock frequency divided by a divisor value.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a resonator clock, in accordance with some embodiments.

FIG. 2 is another resonator clock, in accordance with some embodiments.

FIG. 3 is yet another resonator clock, in accordance with some embodiments.

FIG. 4 illustrates a single side band mixer, in accordance with some embodiments.

FIG. 5 is another single side band mixer, in accordance with some embodiments.

FIG. 6 is a flow diagram of a clock generating method, in accordance with some embodiments.

FIG. 7 is a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments of a resonator clock are disclosed. The resonator clock includes a first oscillator circuit that utilizes a first acoustic wave device to generate a first oscillator clock signal and a second oscillator circuit that utilizes a second acoustic wave device to generate a second oscillator clock signal. One or more output clock signals are derived from the first oscillator clock signal through one or more frequency dividers, which reduces phase noise. A phase lock loop then generates a reference clock signal having a reference clock frequency that is based on the frequency offset between the first oscillator clock signal and the second oscillator clock signal. The first acoustic wave device and the second acoustic wave device may be monolithic and thus may be manufactured in proximity to each other so that the relevant thicknesses and material parameters of layers in the first acoustic wave device and the second acoustic wave device are nearly identical. The temperature and mechanical response of the first acoustic wave device and the second acoustic wave device will therefore be nearly the same. However, at least one layer in the first acoustic wave device and at least one layer in the second acoustic wave device may be purposely designed to be different. Accordingly, the frequency offset between the first oscillator clock signal and the second oscillator clock signal may be small but predetermined accurately, thereby resulting in more stable temperature and stress behavior. By carefully choosing the layers in the first acoustic wave device and the second acoustic wave device that are designed to be different, the temperature coefficients can be tailored to create a situation where the frequency offset is more stable over temperature and less impacted by package induced stress.

The frequency offset is then used to control the primary oscillator frequency through a phase lock loop to reduce effects of temperature and stress. The bandwidth of the phase lock loop can be very low as temperature and stress-changes occur very slowly. Therefore, a degradation of phase noise can be avoided for the part of the spectrum that matters most. Furthermore, the frequency offset may be stable over temperature and stress.

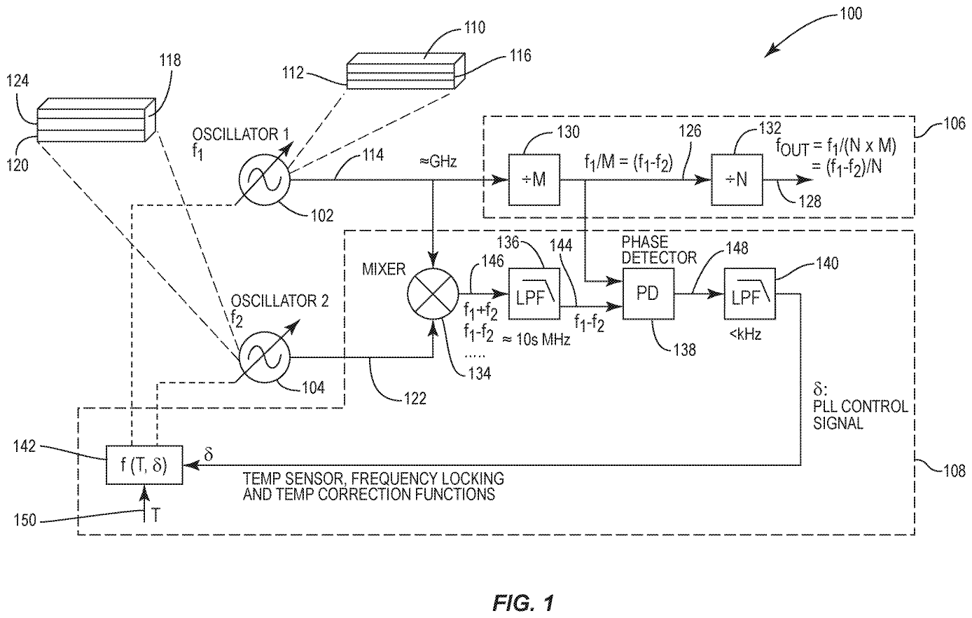

FIG. 1 is a resonator clock 100, in accordance with some embodiments.

The resonator clock 100 has a first oscillator circuit 102, a second oscillator circuit 104, an output clock circuit 106, and a phase lock loop 108. The first oscillator circuit 102 includes a first acoustic wave device 110. The first oscillator circuit 102 uses the first acoustic wave device 110 by leveraging the ability of the first acoustic wave device 110 to naturally oscillate at specific frequencies. In particular, the first acoustic wave device 110 defines a resonant frequency of oscillation. The first oscillator circuit 102 is configured to apply an alternating voltage to the first acoustic wave device 110. The first acoustic wave device 110 includes at least one piezoelectric substrate 112 that converts the alternating voltage into mechanical waves through the direct piezoelectric effect. The first acoustic wave device 110 then converts mechanical waves into an electrical signal through the inverse piezoelectric effect such that the first oscillator circuit 102 generates a first oscillator clock signal 114 having a first oscillator signal frequency, f₁. In some embodiments, the first oscillator signal frequency f₁ is the resonant frequency of the first acoustic wave device 110. However, it should be noted that the first oscillator signal frequency f₁ depends on a frequency of the alternating voltage applied by the first oscillator circuit 102 to the first acoustic wave device 110 as well as the characteristics of the first acoustic wave device 110.

In FIG. 1, the first acoustic wave device 110 is a bulk acoustic wave (BAW) device. However, any other suitable type of acoustic wave device may be used as the first acoustic wave device 110 including, a surface acoustic wave (SAW) device, a thickness shear mode (TSM) resonator, a Love wave device, a Lamb wave device, and/or the like. The first acoustic wave device 110 may include a plurality of different layers other than the piezoelectric substrate 112 including electrode layers, reflector layers, and/or the like. One or more of these layers is represented by at least one layer 116. In some embodiments, the first acoustic wave device 110 exhibits a high quality (Q) factor, meaning that the first acoustic wave device 110 acts as a highly frequency-selective filter, allowing only a narrow band of frequencies around its resonant frequency to pass through as the first oscillator clock signal 114.

The second oscillator circuit 104 includes a second acoustic wave device 118. The second oscillator circuit 104 uses the second acoustic wave device 118 by leveraging the ability of the second acoustic wave device 118 to naturally oscillate at specific frequencies. In particular, the second acoustic wave device 118 defines a resonant frequency of oscillation. The second oscillator circuit 104 is configured to apply an alternating voltage to the second acoustic wave device 118. The second acoustic wave device 118 includes at least one piezoelectric substrate 120 that converts the alternating voltage into mechanical waves through the direct piezoelectric effect. The second acoustic wave device 118 then coverts mechanical waves into an electrical signal through the inverse piezoelectric effect such that the second oscillator circuit 104 generates a second oscillator clock signal 122 having a second oscillator signal frequency, f₂. In some embodiments, the second oscillator signal frequency f₂ is the resonant frequency of the second acoustic wave device 118. However, it should be noted that the second oscillator signal frequency f₂ depends on a frequency of the alternating voltage applied by the second oscillator circuit 104 to the second acoustic wave device 118 as well as the characteristics of the second acoustic wave device 118.

In FIG. 1, the second acoustic wave device 118 is a BAW device. However, any other suitable type of acoustic wave device may be used as the second acoustic wave device 118 including, a SAW device, a TSM resonator, a Love wave device, a Lamb wave device, and/or the like. The second acoustic wave device 118 may include a plurality of different layers other than the piezoelectric substrate 120 including electrode layers, reflector layers, and/or the like. One or more of these layers is represented by at least one layer 124. In some embodiments, the second acoustic wave device 118 exhibits a high quality (Q) factor, meaning that the second acoustic wave device 118 acts as a highly frequency-selective filter, allowing only a narrow band of frequencies around its resonant frequency to pass through as the second oscillator clock signal 122.

In FIG. 1, the first acoustic wave device 110 and the second acoustic wave device 118 are different such that the first oscillator clock frequency f₁ and the second oscillator clock frequency f₂ are different. In some embodiments, the first acoustic wave device 110 and the second acoustic wave device 118 are monolithic but are different by having the at least one layer 116 and the at least one layer 124 be different such that the first resonator clock frequency and the second resonator clock frequency are different. Thus, the first acoustic wave device 110 and the second acoustic wave device 118 may be monolithic by being fabricated with a common piezoelectric substrate that is later diced so as to create the separate the first acoustic wave device 110 and the second acoustic wave device 118. However, by making the at least one layer 116 and the at least one layer 124 different by design, one can predetermine a frequency offset in the first oscillator clock frequency f₁ and the second oscillator clock frequency f₂, which is referred to as Δ=f₁−f₂.

The output clock circuit 106 is configured to generate an intermediary output clock signal 126 and a final output clock signal 128. More specifically, the output clock circuit 106 includes an intermediary frequency divider 130 and a final frequency divider 132. The intermediary frequency divider 130 is configured to receive the first oscillator clock signal 114 and, in response to the first oscillator clock signal 114, generate the intermediary output clock signal 126. The intermediary output clock signal 126 has an intermediary output clock signal frequency that is the first oscillator clock frequency f₁ divided by a divisor value M. The divisor value M may be an integer value such as, 2, 3, 5, etc. In some embodiments, the intermediary frequency divider 130 achieves this frequency division in several frequency division stages. Thus, the frequency offset Δ may be selected to be integer multiple of the first oscillator clock frequency f₁, and both the first oscillator clock frequency f₁ and the second oscillator clock frequency f₂ may be chosen as an integer multiple of the frequency offset Δ. In some embodiments, the first oscillator clock frequency f₁ may be equal to or greater than 1 GHz. In some embodiments, the second oscillator clock frequency f₂ may be equal to or greater than 1 GHz. In some embodiments, the frequency offset Δ may be between 1 MHz and 1 GHz.

The final frequency divider 132 is configured to receive the intermediary output clock signal 126 and, in response to the intermediary output clock signal 126, generate the final output clock signal 128. The final output clock signal 128 has a final output clock signal frequency that is the intermediary oscillator clock frequency f₁/M divided by a divisor value N (i.e., the final output clock signal frequency is equal to f₁/(M*N)). The divisor value N may be an integer value such as, 2, 3, 5, etc. In some embodiments, the final frequency divider 132 achieves this frequency division in several frequency division stages.

The phase lock loop 108 includes a double side band mixer 134, a low pass filter 136, a phase detector 138, a low pass filter 140, and a frequency control circuit 142. The double side band mixer 134 is configured to mix the first oscillator clock signal 114 and the second oscillator clock signal 122 so that the phase lock loop 108 is configured to generate a reference clock signal 144 having a reference clock frequency. The reference clock frequency is related to frequency offset Δ. In some embodiments, the reference clock frequency is equal to frequency offset Δ.

In this embodiment, the double side band mixer 134 is a double side band mixer that is configured to generate a composite reference clock signal 146 having a higher frequency reference clock signal and a lower frequency reference clock signal. The higher frequency reference clock signal has a frequency equal to the first oscillator clock frequency f₁ added to the second oscillator clock frequency f₂, and the lower frequency reference clock signal has a frequency equal to the first oscillator clock frequency f₁ minus the second oscillator clock frequency f₂. The low pass filter is configured to filter the higher frequency reference clock signal from the composite reference clock signal 146 so that the reference clock signal 144 is generated as the lower frequency reference clock signal. The phase detector 138 is configured to receive the reference clock signal 144 and the intermediary output clock signal 126 and generate a phase error signal 148 that indicates the frequency offset Δ between the intermediary output clock signal 126 and the reference clock signal 144. The low pass filter 140 then filters the phase error signal 148. More specifically, a bandwidth of the phase lock loop 108 can be very low as temperature and stress changes occur very slowly in comparison to the frequency of the first oscillator clock frequency f₁ and the first oscillator clock frequency f₂. For example, the difference between the bandwidth of the phase lock loop 108 and the first oscillator clock frequency f₁ and the first oscillator clock frequency f₂ may be between one or two orders of magnitude. Therefore, a degradation of phase noise in the phase error signal 148 can be avoided for the part of the spectrum of the phase error signal 148 that matters most. After filtering by the low pass filter 140, the phase error signal 148 may be in a frequency range of 1 kHz or less.

The phase lock loop 108 is configured to drive the intermediary output clock frequency of the intermediary output clock signal 126 to a set relationship with the reference clock frequency of the reference clock signal 144 based on the phase error signal 148. In some embodiments, the phase lock loop 108 is configured to drive the intermediary output clock frequency of the intermediary output clock signal 126 to be equal to the reference clock frequency of the reference clock signal 144. To do this, the frequency control circuit 142 is configured to receive the phase error signal 148 from the output of the low pass filter 140. In response, the frequency control circuit 142 adjusts the alternating input signal to the acoustic wave device 110 until the intermediary output clock frequency of the intermediary output clock signal 126 has the set relationship with the reference clock frequency of the reference clock signal 144 as indicated by the phase error signal 148, which indicates the offset frequency Δ. If the first oscillation frequency f₁ begins to drift, the phase lock loop 108 is responsive and adjusts the first oscillation frequency f₁ to correct the first oscillation frequency f₁ and maintain the first oscillation frequency f₁

It should be noted that the frequency control circuit 142 may also be configured to receive a temperature input signal 150 that indicates at least one temperature of the resonator clock 100 (one or more temperatures of any of one or more of the components in the resonator clock 100). In this manner, the frequency control circuit 142 is configured to maintain the offset frequency Δ with maximum stability over temperature and stress. In some embodiments, the frequency control circuit 142 is configured to shift the first oscillator frequency f₁ and/or the second oscillator frequency f₂ by an amount determined by a mathematical function (for example, a polynomial that is established during a calibration procedure) in response to the temperature input signal 150 and/or the phase error signal 148. The frequency control circuit 142 may be configured to shift the first oscillator frequency f₁ and/or the second oscillator frequency f₂ with a variable capacitance (either parallel or in series with the first acoustic wave device 110 and/or the second acoustic wave device 118 (‘pulling’)), or by applying a direct current-bias voltage directly to the acoustic wave device 110 and/or the acoustic wave device 118. Any other technique of frequency adjustment may also be implemented to adjust the first oscillator frequency f₁ and/or the second oscillator frequency f₂. In some embodiments, power consumption is reduced in the system by turning off the second oscillator circuit 104 and then turning on the second oscillator circuit 104 for operation of the phase lock loop 108. The second oscillator circuit 104 does not have to operate continuously as the phase lock loop 108 is very slow and can be powered up periodically to create correct the first oscillator frequency f₁ of the first oscillator circuit 102. Phase noise of the second oscillator clock signal 122 is less critical, as most of the spectrum is filtered out by the low pass filter 140 in the phase lock loop 108.

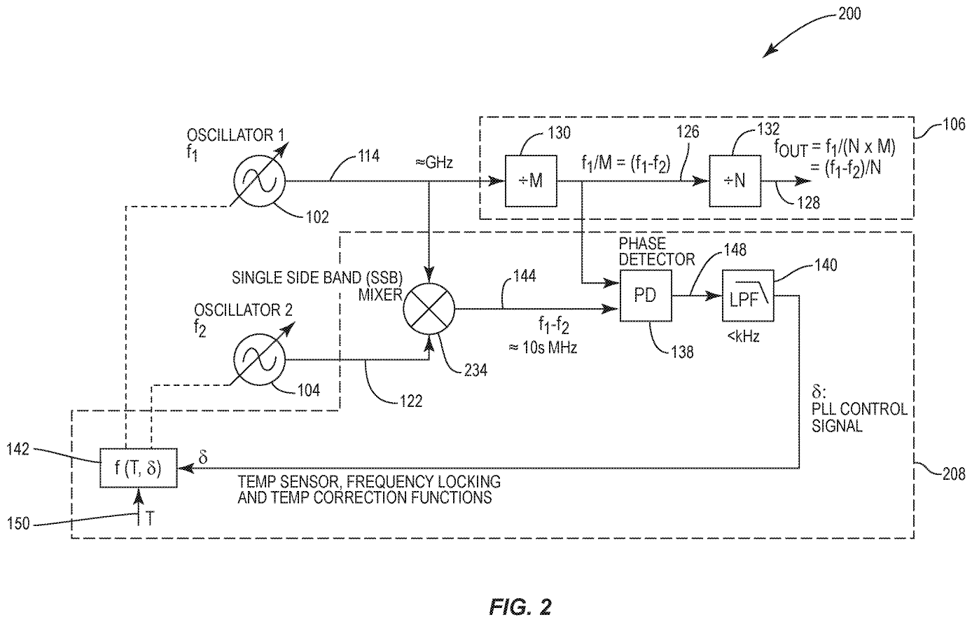

FIG. 2 is another resonator clock 200, in accordance with some embodiments.

The resonator clock 200 is the same as the resonator clock 100 except for a phase lock loop 208 of the resonator clock 200. More specifically, the phase lock loop 208 includes the phase detector 138, the low pass filter 140, and the frequency control circuit 142, which operate in the same manner described above with respect to FIG. 1. However, the phase lock loop 208 shown in FIG. 2 includes a single side band mixer 234 that is configured to directly generate the reference clock signal 144. As explained above, the reference clock signal 144 has a frequency equal to the offset frequency Δ. Thus, unlike the double side band mixer 134 disclosed in FIG. 1, the single side band mixer 234 of FIG. 2 does not generate the higher frequency reference clock signal having the clock frequency of the first oscillator frequency f₁ added to the second oscillator frequency f_{2.} Accordingly, unlike the phase lock loop 108 shown in FIG. 1, the phase lock loop 208 shown in FIG. 2 does not include the low pass filter 136 and instead the phase detector 138 receives the reference clock signal 144 from the single side band mixer 234.

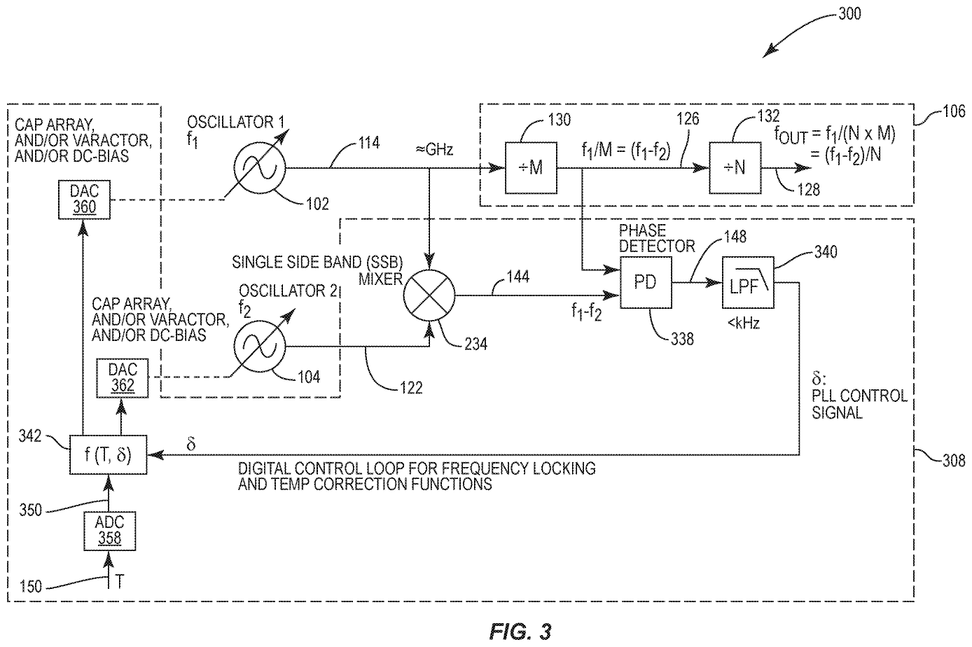

FIG. 3 is yet another resonator clock 300, in accordance with some embodiments.

The resonator clock 300 is the same as the resonator clock 200, except for a phase lock loop 308 of the resonator clock 300. The phase lock loop 308 includes the single side band mixer 234 described above with respect to FIG. 2. A phase detector 338 in FIG. 3 operates in the same manner as the phase detector 138 described above with respect to FIG. 1, except that the phase detector 338 in FIG. 3 is a digital phase detector while the phase detector 138 in FIG. 1 is an analog phase detector. Similarly, a low pass filter 340 in FIG. 3 operates in the same manner as the low pass filter 140 described above with respect to FIG. 1, except that the low pass filter 340 in FIG. 3 is a digital low pass filter while the low pass filter 140 in FIG. 1 is an analog low pass filter. Additionally, a frequency control circuit 342 in FIG. 3 operates in the same manner as the frequency control circuit 142 described above with respect to FIG. 1, except that the frequency control circuit 342 in FIG. 3 is a digital frequency control circuit while the frequency control circuit 142 in FIG. 1 is an analog low pass filter.

Accordingly, the phase lock loop 308 includes an analog-to-digital converter (ADC) 358 that is configured to convert the temperature input signal 150 into a digital temperature input signal 350 that is received by the frequency control circuit 342. Additionally, a digital-to-analog converter 360 is provided between the frequency control circuit 342 and the first oscillator circuit 102 so that digital control signals from the frequency control circuit 342 are converted into analog control signals that adjust the first oscillator frequency f₁. Also, a digital-to-analog converter 362 is provided between the frequency control circuit 342 and the second oscillator circuit 104 so that digital control signals from the frequency control circuit 342 are converted into analog control signals that adjust the second oscillator frequency f₂.

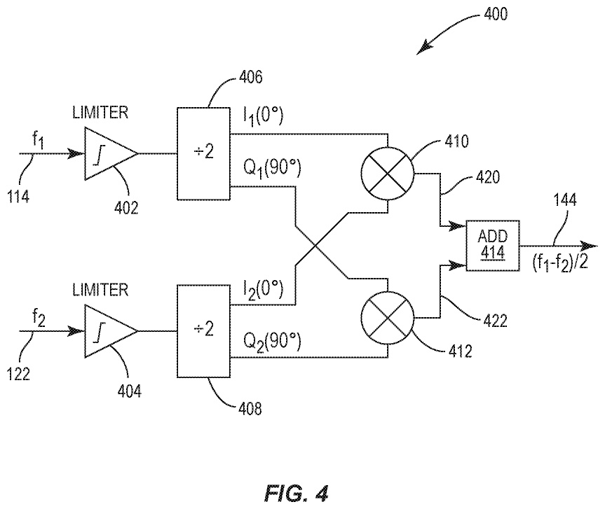

FIG. 4 illustrates a single side band mixer 400, in accordance with some embodiments.

In some embodiments, the single side band mixer 234 is FIG. 2 and/or FIG. 3 is provided in the same manner as the single side band mixer 400 shown in FIG. 4. The single side band mixer 234 includes a limiter 402, a limiter 404, an IQ converter 406, an IQ converter 408, a mixer 410, a mixer 412, and an adder 414.

The limiter 402 is configured to receive the first oscillator clock signal 114 and limit both the positive and negative maximum voltage levels of the first oscillator clock signal 114 to a maximum voltage magnitude. The first oscillator clock signal 114 can thus now be considered converted from an analog clock signal to a digital clock signal. The first oscillator clock signal 114 is received by the IQ converter 406, which is configured to convert the first oscillator clock signal 114 into an in-phase signal I₁ and a quadrature phase signal Q₁.

The limiter 404 is configured to receive the second oscillator clock signal 122 and limit both the positive and negative maximum voltage levels of the second oscillator clock signal 122 to a maximum voltage magnitude. The second oscillator clock signal 122 can thus now be considered converted from an analog clock signal to a digital clock signal. The second oscillator clock signal 122 is received by the IQ converter 408, which is configured to convert the second oscillator clock signal 122 into an in-phase signal I₂ and a quadrature phase signal Q₂.

The mixer 410 is configured to mix the in-phase signal I₁ and the in-phase signal I₂ to generate mixed in-phase signal 420. The mixer 412 is configured to mix the quadrature signal Q₁ and the quadrature signal Q₂ to generate mixed quadrature signal 422. The mixed in phase signal 420 and the mixed quadrature signal 422 are then received by the adder 414 to generate the reference clock signal 144. Note that the reference clock signal 144 is illustrated as having a frequency of the offset frequency Δ/2. However, the divisor of 2 is assumed to be subsumed within the divisor M shown for the intermediary frequency divider 130 shown in FIG. 2 and FIG. 3. Thus, the intermediary frequency divider 130 shown in FIG. 2 and FIG. 3, may on its own divide by a divisor value of M/2.

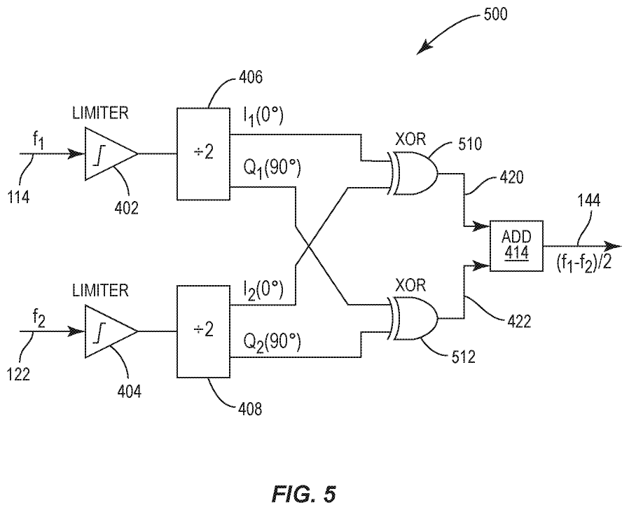

FIG. 5 is another single side band mixer 500, in accordance with some embodiments.

The single side band mixer 500 is the same as the single side band mixer 400 shown in FIG. 4 except that the single side band mixer 500 in FIG. 5 has an XOR gate 510 instead of the mixer 410 in FIG. 4 and has an XOR gate 512 instead of the mixer 412 in FIG. 4. However, the XOR gate 510 in FIG. 5 functionally provides the same operation as the mixer 410 in FIG. 4. Thus, the XOR gate 510 is configured to mix the in-phase signal I₁ and the in-phase signal I₂ to generate mixed in phase signal 420. Additionally, the XOR gate 512 in FIG. 5 functionally provides the same operation as the mixer 412 in FIG. 4. Thus, the XOR gate 512 is configured to mix the quadrature signal Q₁ and the quadrature signal Q₂ to generate mixed quadrature signal 422.

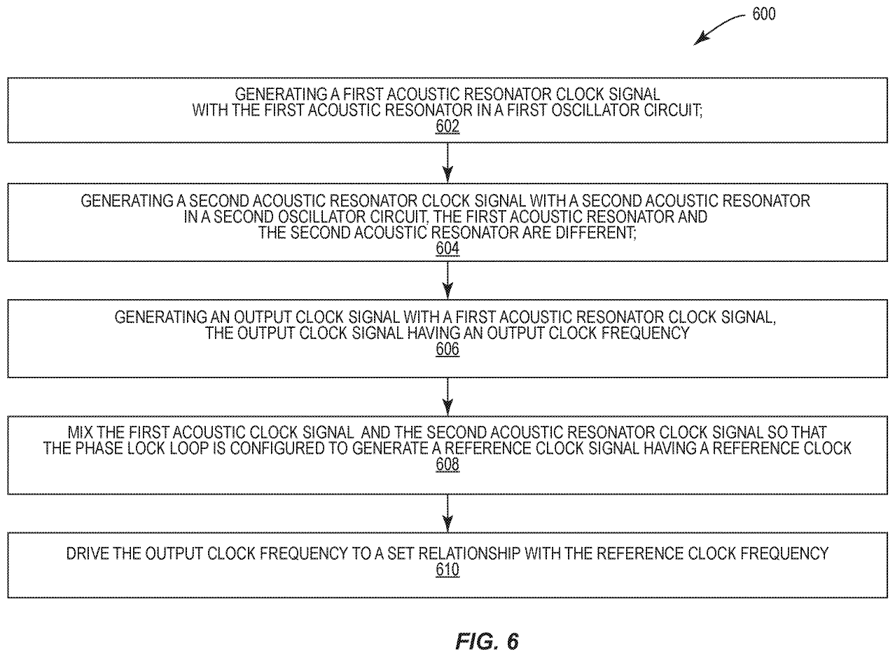

FIG. 6 is a flow diagram 600 of a clock generating method, in accordance with some embodiments.

The flow diagram 600 may be performed by the resonator clock 100 in FIG. 1, the resonator clock 200 shown in FIG. 2, and the resonator clock 300 shown in FIG. 3, in accordance with some embodiments. Flow diagram 600 includes blocks 602-610. Flow begins at block 602.

At block 602, a first oscillator clock signal is generated with the first acoustic wave device in a first oscillator circuit. An example of the first oscillator clock signal is the first oscillator clock signal 114 shown in FIG. 1, in FIG. 2, and in FIG. 3. An example of the first acoustic wave device is the first acoustic wave device 110 shown in FIG. 1. An example of the first oscillator circuit is the first oscillator circuit 102 shown in FIG. 1, in FIG. 2, and in FIG. 3. Flow then proceeds to block 604.

At block 604, a second oscillator clock signal is generated with the first acoustic wave device in a second oscillator circuit. An example of the second oscillator clock signal is the second oscillator clock signal 122 shown in FIG. 1, in FIG. 2, and in FIG. 3. An example of the second acoustic wave device is the second acoustic wave device 118 shown in FIG. 1. An example of the second oscillator circuit is the second oscillator circuit 104 shown in FIG. 1, in FIG. 2, and in FIG. 3. Flow then proceeds to block 606.

At block 606, an output clock signal is generated with a first oscillator clock signal, the output clock signal having an output clock frequency. An example of the output clock signal is the intermediary output clock signal 126 shown in FIG. 1, in FIG. 2, and in FIG. 3. In some embodiments, the output clock circuit 106 shown in FIG. 1, in FIG. 2, and in FIG. 3 performs block 606. Flow then proceeds to block 608.

At block 608, the first oscillator clock signal and the second oscillator clock signal are mixed so that a phase lock loop is configured to generate a reference clock signal having a reference clock frequency. In some embodiments, the reference clock signal is the reference clock signal 144 shown in FIG. 1, in FIG. 2, in FIG. 3, in FIG. 4, and in FIG. 5. In some embodiments, block 608 is performed by the double side band mixer 134 shown in FIG. 1, by the single side band mixer 234 shown in FIG. 2 and FIG. 3, by the single side band mixer 400 shown in FIG. 4, or by the single side band mixer 500 shown in FIG. 5. In some embodiments, the phase lock loop is the phase lock loop 108 shown in FIG. 1, the phase lock loop 208 shown in FIG. 2, or the phase lock loop 308 shown in FIG. 3. Flow then proceeds to block 610.

At block 610, the output clock frequency is driven to a set relationship with the reference clock frequency. In some embodiments, block 610 is performed by the phase lock loop 108 shown in FIG. 1, the phase lock loop 208 shown in FIG. 2, or the phase lock loop 308 shown in FIG. 3.

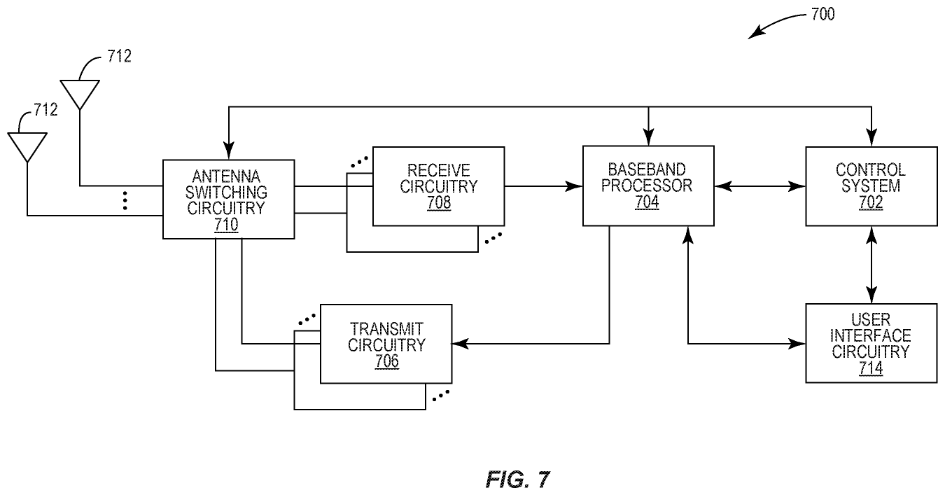

FIG. 7 is a user element 700, in accordance with some embodiments.

With reference to FIG. 7, the concepts described above may be implemented in various types of user elements 700, such as mobile terminals, smart watches, tablets, computers, navigation devices, access points, and the like wireless communication devices that support wireless communications, such as cellular, wireless local area network (WLAN), Bluetooth, and near-field communications. The user element 700 generally include a control system 702, a baseband processor 704, transmit circuitry 706, receive circuitry 708, antenna switching circuitry 710, multiple antennas 712, and user interface circuitry 714. In a non-limiting example, the control system 702 may be a field-programmable gate array (FPGA) or an application-specific integrated circuit (ASIC). In this regard, the control system 702 may include at least a microprocessor, an embedded memory circuit, and a communication bus interface. The receive circuitry 708 receives radio frequency signals via the antennas 712 and through the antenna switching circuitry 710 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 704 processes the digitized received signal to extract the information or data bits conveyed in the received signal. This processing typically comprises demodulation, decoding, and error correction operations, as will be discussed in greater detail below. The baseband processor 704 is generally implemented in one or more digital signal processors (DSPs) and application-specific integrated circuits (ASICs).

For transmission, the baseband processor 704 receives digitized data, which may represent voice, data, or control information, from the control system 702, which it encodes for transmission. The encoded data is output to the transmit circuitry 706, where a digital-to-analog converter (DAC) converts the digitally encoded data into an analog signal and a modulator modulates the analog signal onto a carrier signal that is at a desired transmit frequency or frequencies. A power amplifier amplifies the modulated carrier signal to a level appropriate for transmission and delivers the modulated carrier signal to the antennas 712 through the antenna switching circuitry 710. The multiple antennas 712 and the replicated transmit circuitry 706 and receive circuitry 708 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A resonator clock, comprising:
a first oscillator circuit comprising a first acoustic wave device, wherein the first oscillator circuit is configured to generate a first oscillator clock signal with the first acoustic wave device;
a second oscillator circuit comprising a second acoustic wave device, wherein the second oscillator circuit is configured to generate a second oscillator clock signal with the second acoustic wave device, and wherein the first acoustic wave device and the second acoustic wave device are different;
an output clock circuit configured to receive the first oscillator clock signal and generate an output clock signal having an output clock frequency; and
a phase lock loop, wherein:
the phase lock loop comprises a mixer configured to mix the first oscillator clock signal and the second oscillator clock signal so that the phase lock loop is configured to generate a reference clock signal having a reference clock frequency; and
the phase lock loop is configured to drive the output clock frequency to a set relationship with the reference clock frequency.

2. The resonator clock of claim 1, wherein the first acoustic wave device and the second acoustic wave device are different such that the first oscillator clock signal has a first oscillator clock frequency and the second oscillator clock signal has a second oscillator clock frequency, and wherein the first oscillator clock frequency and the second oscillator clock frequency are different.

3. The resonator clock of claim 2, wherein the first acoustic wave device and the second acoustic wave device are monolithic but are different by having at least one layer that is different such that the first oscillator clock frequency and the second oscillator clock frequency are different.

4. The resonator clock of claim 1, wherein the set relationship is the output clock frequency equaling the reference clock frequency.

5. The resonator clock of claim 4, wherein the output clock circuit comprises a frequency divider, wherein the frequency divider is configured to:
receive the first oscillator clock signal having a first oscillator clock frequency;
generate the output clock signal in response to the first oscillator clock signal, the output clock signal having an output clock signal frequency that is the first oscillator clock frequency divided by an divisor value.

6. The resonator clock of claim 5, wherein:
the frequency divider is an intermediary frequency divider;
the output clock signal is an intermediary output clock signal;
the output clock signal has an intermediary output clock signal frequency;
the divisor value is an intermediary divisor value;
the output clock circuit further comprises a final frequency divider; and
the final frequency divider is configured to:
receive the intermediary output clock signal; and
generate a final output clock signal in response to the intermediary output clock signal, the final output clock signal having a final output clock signal frequency that is the intermediary output clock signal frequency divided by a second divisor value.

7. The resonator clock of claim 1, wherein:
the first acoustic wave device and the second acoustic wave device are different such that the first oscillator clock signal has a first oscillator clock frequency and the second oscillator clock signal has a second oscillator clock frequency and wherein the first oscillator clock frequency and the second oscillator clock frequency are different;
the mixer is a double side band mixer that is configured to generate a composite reference clock signal having a higher frequency reference clock signal and a lower frequency reference clock signal, the higher frequency reference clock signal having a frequency equal to the first oscillator clock frequency added to the second oscillator clock frequency, and the lower frequency reference clock signal having a frequency equal to the first oscillator clock frequency minus the second oscillator clock frequency; and
the phase lock loop further comprises
a low pass filter configured to filter the higher frequency reference clock signal from the composite reference clock signal so that a reference clock signal is generated that is the lower frequency reference clock signal; and
a phase detector configured to receive the reference clock signal and the output clock signal and generate a phase error signal that indicates a frequency difference between the output clock signal and the reference clock signal.

8. The resonator clock of claim 7, wherein the low pass filter is a first low pass filter, and the phase detector comprises a second low pass filter that is configured to filter the phase error signal.

9. The resonator clock of claim 7, further comprising a control circuit operably associated with the first oscillator circuit, wherein the control circuit is configured to drive the output clock frequency to the set relationship with the reference clock frequency based on the phase error signal.

10. The resonator clock of claim 1, wherein:
the first acoustic wave device and the second acoustic wave device are different such that the first oscillator clock signal has a first oscillator clock frequency and the second oscillator clock signal has a second oscillator clock frequency and wherein the first oscillator clock frequency and the second oscillator clock frequency are different;
the mixer is a single side band mixer that is configured to generate a reference clock signal having a frequency equal to the first oscillator clock frequency minus the second oscillator clock frequency; and
the phase lock loop further comprises a phase detector configured to receive the reference clock signal and the output clock signal and generate a phase error signal that indicates a frequency difference between the output clock signal and the reference clock signal.

11. The resonator clock of claim 10, further comprising a control circuit operably associated with the first oscillator circuit, wherein the control circuit is configured to drive the output clock frequency to the set relationship with the reference clock frequency based on the phase error signal.

12. The resonator clock of claim 10, the mixer is a first mixer and wherein the single side band mixer comprises:
a first I/Q generator circuit configured to generate a first in-phase signal and a first quadrature signal based on the first oscillator clock signal;
a second I/Q generator circuit configured to generate a second in-phase signal and a second quadrature signal based on the second oscillator clock signal;
a second mixer configured to mix the first in-phase signal and the second in-phase signal so as to generate a mixed in-phase signal;
a third mixer configured to mix the first quadrature signal and the second quadrature signal to generate a mixed quadrature signal; and
a signal adder configured to add the mixed in-phase signal and the mixed quadrature signal so as to generate the reference clock signal.

13. The resonator clock of claim 10, wherein the single side band mixer comprises:
a first I/Q generator circuit configured to generate a first in-phase signal and a first quadrature signal based on first oscillator clock signal;
a second I/Q generator circuit configured to generate a second in-phase signal and a second quadrature signal based on second oscillator clock signal;
a first XOR gate configured to mix the first in-phase signal and the second in-phase signal so as to generate a mixed in-phase signal;
a second XOR gate configured to mix the first quadrature signal and the second quadrature signal to generate a mixed quadrature signal; and
a signal adder configured to add the mixed in-phase signal and the mixed quadrature signal so as to generate the reference clock signal.

14. The resonator clock of claim 10, wherein the control circuit is a digital control circuit, the phase lock loop further comprising:
a first digital-to-analog converter between the digital control circuit and the first oscillator circuit;
a second digital-to-analog converter between the digital control circuit and the second oscillator circuit.

15. A clock generating method, comprising:
generating a first oscillator clock signal with a first acoustic wave device in a first oscillator circuit;
generating a second oscillator clock signal with a second acoustic wave device in a second oscillator circuit, wherein the first acoustic wave device and the second acoustic wave device are different;
generate an output clock signal with a first oscillator clock signal, the output clock signal having an output clock frequency;
mix the first oscillator clock signal and the second oscillator clock signal so that the phase lock loop is configured to generate a reference clock signal having a reference clock frequency; and
drive the output clock frequency to a set relationship with the reference clock frequency.

16. A user element comprising a reference clock, the reference clock comprising:
a first oscillator circuit comprising a first acoustic wave device, wherein the first oscillator circuit is configured to generate a first oscillator clock signal with the first acoustic wave device;
a second oscillator circuit comprising a second acoustic wave device, wherein the second oscillator circuit is configured to generate a second oscillator clock signal with the second acoustic wave device, wherein the first acoustic wave device and the second acoustic wave device are different; and
an output clock circuit configured to receive the first oscillator clock signal and generate an output clock signal having an output clock frequency;
a phase lock loop, wherein:
the phase lock loop comprises a mixer configured to mix the first oscillator clock signal and the second oscillator clock signal so that the phase lock loop is configured to generate a reference clock signal having a reference clock frequency; and
the phase lock loop is configured to drive the output clock frequency to a set relationship with the reference clock frequency.

17. The user element of claim 16, wherein the first acoustic wave device and the second acoustic wave device are different such that the first oscillator clock signal has a first oscillator clock frequency and the second oscillator clock signal has a second oscillator clock frequency, and wherein the first oscillator clock frequency and the second oscillator clock frequency are different.

18. The user element of claim 17, wherein the first acoustic wave device and the second acoustic wave device are monolithic but are different by having at least one layer that is different such that the first oscillator clock frequency and the second oscillator clock frequency are different.

19. The user element of claim 16, wherein the set relationship is the output clock frequency equaling the reference clock frequency.

20. The user element of claim 19, wherein the output clock circuit comprises a frequency divider wherein the frequency divider is configured to:
receive the first oscillator clock signal having a first oscillator clock frequency;
generate the output clock signal in response to the first oscillator clock signal, the output clock signal having an output clock signal frequency that is the first oscillator clock frequency divided by a divisor value.
